(19) United States
(12) Patent Application Publication
(10) Pub. No.: US 2026/0123209 A1
(43) Pub. Date: Apr. 30, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Kye Uk LEE, Yongin-si (KR); Seung Soo BAEK, Yongin-si (KR); Sun Kwang KIM, Yongin-si (KR); Si Hyun AHN, Yongin-si (KR)

(21) Appl. No.: 19/090,789

(22) Filed: Mar. 26, 2025

(30) Foreign Application Priority Data
Oct. 30, 2024 (KR) 10-2024-0151003

(51) Int. Cl. H10K 59/131

(52) U.S. Cl. CPC H10K 59/131

(57) ABSTRACT

A display device includes: a display panel including a display area and a non-display area; a first power line formed in a first layer of the non-display area; and a second power line including a first part that is formed in the first layer and a second part that is formed in a second layer of the non-display area so as to be overlapped with the first power line, wherein the first power line includes first sub-lines that are arranged to form a mesh structure, and the second power line includes second sub-lines that are arranged to form the mesh structure, and wherein a plurality of first intersection points, which are formed by intersections between the first sub-lines of the first power line, and a plurality of second intersection points, which are formed by intersections between the second sub-lines of the second power line, do not overlap each other.

### CROSS-REFERENCE TO RELATED APPLICATION

This application claims priority under 35 U.S.C. § 119 to Korean Patent Application No. 10-2024-0151003 filed on Oct. 30, 2024 in the Korean Intellectual Property Office (KIPO), the disclosure of which is incorporated by reference herein in its entirety.

### TECHNICAL FIELD

Various embodiments of the present invention relate to a display device and an electronic device including the same.

### DISCUSSION OF THE RELATED ART

Demand for display devices is increasing with the continuous development of multimedia. For example, interest in the display device such as a liquid crystal display (LCD), an organic light emitting display (OLED), or the like is increasing.

The display device may generally include a display panel, which serves to display images, and a driving element (e.g., a display driver integrated-circuit (DDI)). The driving element may be responsible for managing and controlling the operation of the display panel, including the activation and regulation of individual pixels. The display panel may include a display area and a non-display area (or, e.g., a dead space (DS) area). The display area may include a plurality of pixels, and the non-display area may include driving circuits and power lines which supplies power for driving the pixels and ground lines.

In addition, the power lines and the ground lines may be disposed (or formed) in a structure in which at least some parts thereof are overlapped with each other. Due to this overlapping structure, a short circuit of the power lines and the ground lines may occur. In addition, if a short circuit of the power lines and the ground lines occurs, damage to the lines caused by the short circuit may spread due to low resistances of the power line and the ground line. Therefore, a method and configuration for preventing a short circuit of the power lines and the ground lines is currently under development.

### SUMMARY

According to an embodiment of the present invention, a display device includes: a display panel including a display area and a non-display area, wherein the display area includes a plurality of pixels, and the non-display area is disposed adjacent to the display area; a first power line formed in a first layer of the non-display area, and configured to supply driving power to each pixel of the plurality of pixels; and a second power line including a first part that is formed in the first layer and a second part that is formed in a second layer of the non-display area so as to be overlapped with the first power line, and configured to supply common power to each pixel of the plurality of pixels, wherein the first power line includes a plurality of first sub-lines that are arranged to form a mesh structure, and the second power line includes a plurality of second sub-lines that are arranged to form the mesh structure, and wherein a plurality of first intersection points, which are formed by intersections between the plurality of first sub-lines of the first power line, and a plurality of second intersection points, which are formed by intersections between the plurality of second sub-lines of the second power line, do not overlap each other.

In an embodiment of the present invention, the first power line is formed in a source-drain layer of the non-display area.

In an embodiment of the present invention, the second power line includes: a second-1 power line formed in a same layer as the first power line while being spaced apart from the first power line; a second-2 power line formed in a different layer from the second-1 power line; and a contact part which electrically connects the second-1 power line and the second-2 power line to each other.

In an embodiment of the present invention, the second-2 power line is formed in a pixel layer where the plurality of pixels are formed.

In an embodiment of the present invention, the second-1 power line has a solid structure, and the second-2 power line has the mesh structure.

In an embodiment of the present invention, the display device further includes a substrate which has one end connected to the display panel, and which includes a driving element configured to control driving of the display panel.

According to an embodiment of the present invention, a display device includes: a display panel including a display area and a non-display area, wherein the display area includes a plurality of pixels, and the non-display area is disposed adjacent to the display area; a first power line formed in a first layer of the non-display area, and configured to supply driving power to each pixel of the plurality of pixels; and a second power line including a first part that is formed in the first layer and a second part that is formed in a second layer of the non-display area so as to be overlapped with the first power line, and configured to supply common power to each pixel of the plurality of pixels, wherein the first power line includes a plurality of first sub-lines that are arranged in a first direction to form a slit structure, and the second power line includes a plurality of second sub-lines that are arranged in the first direction to form the slit structure, and the plurality of first sub-lines of the first power line do not overlap the plurality of second sub-lines of the second power line.

In an embodiment of the present invention, the first power line is formed in a source-drain layer of the non-display area.

In an embodiment of the present invention, the second power line includes: a second-1 power line formed in a same layer as the first power line while being spaced apart from the first power line; a second-2 power line formed in a different layer from the second-1 power line; and a contact part which electrically connects the second-1 power line and the second-2 power line to each other.

In an embodiment of the present invention, the second-2 power line is formed in a pixel layer where the plurality of pixels are formed.

In an embodiment of the present invention, the second-1 power line has a solid structure, and the second-2 power line has the slit structure.

In an embodiment of the present invention, the display device further includes a substrate which has one end connected to the display panel, and which includes a driving element configured to control driving of the display panel.

According to an embodiment of the present invention, an electronic device includes: a housing; and a display device mounted in the housing, wherein the display device includes: a display panel which includes a display area and a non-display area, wherein the display area includes a plurality of pixels, and the non-display area is disposed adjacent to the display area; a first power line formed in a first layer of the non-display area, and configured to supply driving power to each pixel of the plurality of pixels; and a second power line including a first part that is formed in the first layer and a second part that is formed in a second layer of the non-display area so as to be overlapped with the first power line, and configured to supply common power to each pixel of the plurality of pixels, wherein each of the first power line and the second power line includes a slit structure or a mesh structure.

In an embodiment of the present invention, the first power line includes a plurality of first sub-lines, and when the first power line has the mesh structure, the plurality of first sub-lines are arranged to form the mesh structure, and the second power line includes a plurality of second sub-lines that are arranged to form the mesh structure, and a plurality of first intersection points of the first power line do not overlap a plurality of second intersection points of the second power line.

In an embodiment of the present invention, the first power line includes a plurality of first sub-lines, and when the first power line has the slit structure, the plurality of first sub-lines are arranged in a first direction to form the slit structure, and the second power line includes a plurality of second sub-lines that are arranged in the first direction to form the slit structure, and the plurality of first sub-lines of the first power line do not overlap the plurality of second sub-lines of the second power line.

In an embodiment of the present invention, the second power line includes: a second-1 power line formed in a same layer as the first power line while being spaced apart from the first power line; a second-2 power line formed in a different layer from the second-1 power line; and a contact part which electrically connects the second-1 power line and the second-2 power line to each other.

In an embodiment of the present invention, the first power line and the second-1 power line are formed in a source-drain layer of the non-display area.

In an embodiment of the present invention, the second-2 power line is formed in a pixel layer where the plurality of pixels are formed.

In an embodiment of the present invention, the second-1 power line has a solid structure, and the second-2 power line has the mesh structure or the slit structure.

In an embodiment of the present invention, the electronic device further includes a substrate which has one end connected to the display panel, and which includes a driving element configured to control driving of the display panel.

### BRIEF DESCRIPTION OF THE DRAWINGS

FIG. 1 is a view illustrating a display device according to an embodiment of the present invention.

FIG. 2A is a view illustrating a first power line and a second-1 power line according to an embodiment of the present invention.

FIG. 2B is a view illustrating a second-2 power line and a contact part according to an embodiment of the present invention.

FIG. 2C is a cross-sectional view of an area of a display panel, on which the first power line and a second power line are formed, according to an embodiment of the present invention.

FIG. 2D is a plan view of the area of the display panel, in which the first power line and the second power line are formed, according to an embodiment of the present invention.

FIG. 3A is a view illustrating a first power line and a second-1 power line according to an embodiment of the present invention.

FIG. 3B is a view illustrating a second-2 power line and a contact part according to an embodiment of the present invention.

FIG. 3C is a plan view of an area of a display panel, in which the first power line and a second power line are formed, according to an embodiment of the present invention.

FIG. 4 is a view illustrating an electronic device according to an embodiment of the present invention.

FIG. 5 is a diagram illustrating an electronic device according to an embodiment of the present invention.

### DETAILED DESCRIPTION OF THE EMBODIMENTS

Hereinafter, various embodiments of the present invention will be described with reference to the accompanying drawings. Embodiments of the present invention will be illustrated in the drawings and described in the following detailed description related thereto, but the embodiments are not intended to limit the present invention. It is to be understood that the present invention may, however, be embodied in different forms and thus should not be construed as being limited to the embodiments set forth herein. In the drawings and specification, like reference numerals may refer to like elements, and thus repetitive descriptions may be omitted.

Various embodiments of the present invention and the terms used herein do not limit the technical characteristics described in the present disclosure to specific embodiments, and should be construed to include various modifications, equivalents, or replacements of the embodiments. It is to be understood that a singular form of a noun corresponding to an item may include one or a plurality of the things, unless the relevant context clearly indicates otherwise. As used herein, each of phrases such as “A or B,” “at least one of A and B,” “at least one of A or B,” “A, B or C,” “at least one of A, B and C,” and “at least one of A, B or C” may include any one, or all possible combinations of these items enumerated together in the corresponding one of the phrases.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

It is to be understood that if a component (e.g., a first component) is referred to as “bonded to” or “connected to” another component (e.g., a second component), with or without the term “operatively” or “communicatively,” it means that the component may be bonded to the other component directly (e.g., by wire), wirelessly, or via a third component.

Embodiments of the present invention relate to a display device and an electronic device incorporating the display device. The display device includes a display panel with a display area, where a plurality of pixels are arranged, and a non-display area outside the display area. Embodiments of the present invention may increase the reliability of the power lines in the non-display area by addressing issues related to overlapping power lines and short circuits. The display device may include a configuration where the first and second power lines, which may supply driving and common power to the pixels, are arranged to minimize overlapping areas therebetween, thereby reducing the risk of short circuits and potential damage from such failures.

The first power line and the second power line may be formed in distinct structures, either as a mesh or slit structure, ensuring that the intersection points between the first power line and second power line do not overlap each other. For example, the first power line may be formed in a source-drain layer, while the second power line may be divided into two parts: the second-1 power line, which may be formed in the same layer as the first power line, and the second-2 power line, which may be formed in a different layer. These two parts of the second power line may be electrically connected to each other via a contact part. This layered and structured arrangement between the first power line and the second power line may prevent damage caused by short circuits from spreading, thus increasing the reliability of the display device.

Embodiments of the present invention also provide an electronic device incorporating the display device. The configuration, according to embodiments of the present invention, allows the first and second power lines to be arranged either in mesh or slit configurations depending on specific applications. These configurations may minimize the possibility of electrical failures while maintaining efficient power supply to the pixels in the display panel.

Overall, by reducing overlapping areas of the first and second power lines and using structures such as mesh or slit structures, embodiments of the present invention may not only increase reliability but also prevent the propagation of damage caused by electrical failures.

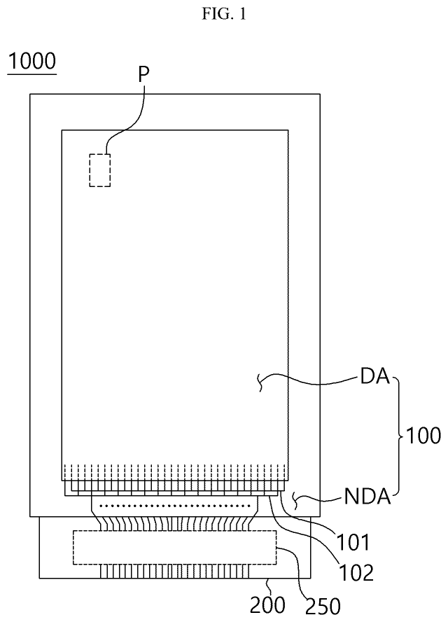

FIG. 1 is a view illustrating a display device according to an embodiment of the present invention.

Referring to FIG. 1, a display device 1000 according to an embodiment of the present invention may include a display panel 100 and a substrate 200.

The substrate 200 may have one end connected with the display panel 100. For example, the substrate 200 may be compression-bonded to the display panel 100 through an adhesive resin such as an anisotropic conductive film (ACF). According to an embodiment of the present invention, the substrate 200 may be formed of a flexible material. For example, the substrate 200 may be a film type flexible printed circuit board (FPCB). The substrate 200 may be bonded with the display panel 100 in a film on glass (FOG) or film on board (FOB) manner.

The substrate 200 may include a driving element (e.g., a driver or driving circuit) 250 which controls driving of the display panel 100 (e.g., light emission of a pixel P). The driving element 250 may receive various power signals and driving signals (e.g., an initialization signal, a scan signal, a data signal, a compensation signal, etc.) for controlling driving of the display panel 100 from an external device (e.g., a main substrate of an electronic device 40 shown in FIG. 4), and supply the received power signals and driving signals to the display panel 100. The driving element 250 may include a display driver integrated-circuit (DDI). The driving element 250 may be coupled to the substrate 200 in, for example, a chip on film (COF) manner. For example, the driving element 250 may be coupled to a central portion of the substrate 200, but the present invention is not limited thereto.

The display panel 100 may output (e.g., display) various images (e.g., still images or moving images). The display panel 100 may be formed of various materials. For example, the display panel 100 may be formed of an inorganic material (e.g., glass) and/or an organic material (such as a metal material, plastic, resin, etc.). The display panel 100 may be formed of a rigid or flexible material. The display panel 100 may be formed to be transparent or opaque.

The display panel 100 may include a display area DA and a non-display area NDA.

The display area DA may display an image (e.g., a still image or moving image). The display area DA may include a plurality of pixels P and a pixel driving element for driving each pixel. For example, the plurality of pixels P may be disposed in the display area DA. The pixel P is a minimum unit that displays an image, and may be an organic light emitting element. This is merely an example, and does not limit the present invention. The pixel driving element may control driving (e.g., light emission) of each pixel. The pixel driving element may include at least one thin film transistor and at least one capacitor, but the present invention is not limited thereto.

The non-display area NDA is formed around (e.g., outside) the display area DA, and the pixel P might not be formed thereon. For example, the non-display area NDA may be adjacent to the display area DA and may at least partially surround the display area DA. For example, the non-display areas NDA may be formed on a lower side, upper side, left side, and right side of the display area DA. The non-display area NDA may include various lines. For example, the non-display area NDA may include a first power line 101, which is for supply driving power to each pixel P, and a second power line 102, which is for supplying common power to each pixel P. In addition, the non-display area NDA may further include lines for providing image signals, lines for touch recognition, etc.

As used herein, the terms “first power lines 101” and “second power lines 102” are used as collective terms, and may each include a plurality of sub-lines, respectively. In particular, for the convenience of description, the sub-lines included in the second power line 102 are also referred to as “some parts or some other parts,” which will also be collectively referred to as second-1 and second-2 power lines, respectively.

A driving voltage ELVDD may be applied to the first power line 101. In addition, a common voltage ELVSS may be applied to the second power line 102. However, they are not limited thereto, and the common voltage ELVSS may be applied to the first power line 101, and the driving voltage ELVDD may be applied to the second power line 102.

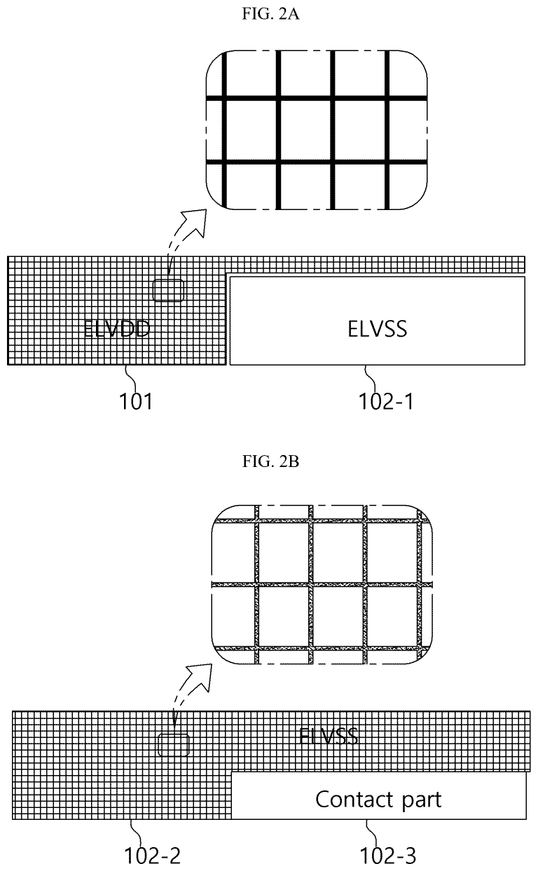

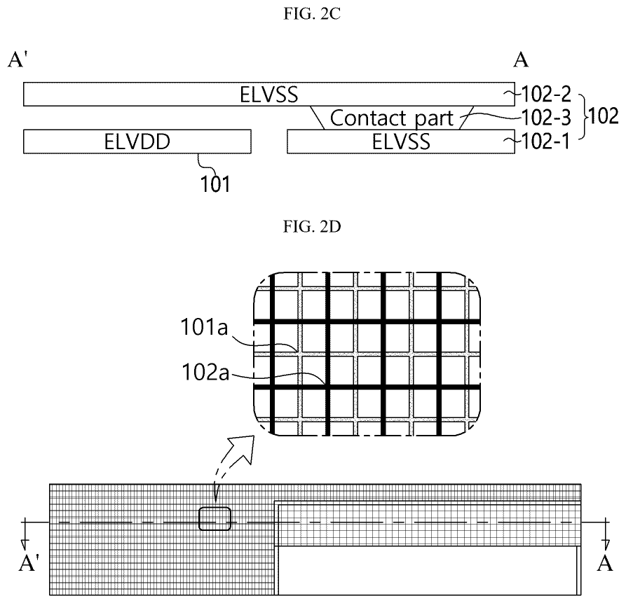

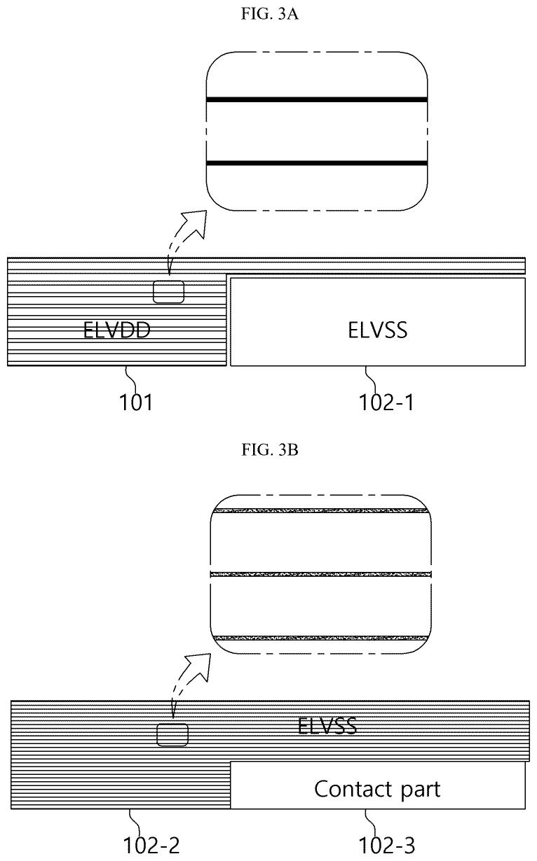

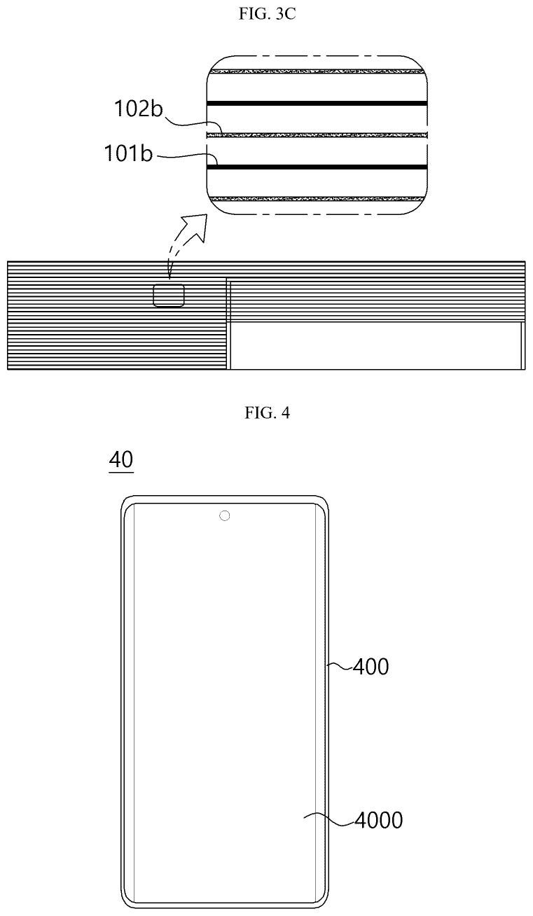

The first power line 101 may be formed in any one layer (e.g., a first layer) of the non-display area NDA. Some parts of the second power line 102 may be formed in the same layer as the first power line 101, and some other parts of the second power line 102 may be formed in a different layer (e.g., a second layer). For example, the first power line 101 may be formed in a source-drain layer, some parts of the second power line 102 may be formed in the source-drain layer, and some other parts of the second power line 102 may be formed in a pixel layer where the pixels P are typically formed. In addition, although FIG. 1 illustrates that the first power line 101 and the second power line 102 are formed as being long in a first direction (e.g., an X-axis direction) in the non-display area NDA without overlapping each other, but this is merely for the convenience of description, and some other parts of the second power line 102 and the first power line 101 may be overlapped with each other on a plane. This structure of the first power line 101 and the second power line 102 will be described in detail below with reference to FIGS. 2A to 3C.

According to an embodiment of the present invention, the first power line 101 and the second power line 102 may be formed in a mesh type (e.g., a mesh structure and/or pattern), and a plurality of sub-lines (e.g., a plurality of first sub-lines of the first power line 101 and a plurality of second sub-lines of the second power line 102) are arranged to form a mesh (e.g., grid or matrix) structure (e.g., the mesh structure of the first power line 101 and the mesh structure of the second power line 102), which will be described in detail below with reference to FIGS. 2A to 2D. As another example, the first power line 101 and the second power line 102 may be formed in a slit type (e.g., a slit pattern or slit structure), and a plurality of sub-lines (e.g., a plurality of first sub-lines of the first power line 101 and a plurality of second sub-lines of the second power line 102) are arranged in a first direction (e.g., horizontal direction), which will be described in detail below with reference to FIGS. 3A to 3C. For example, in the slit type (e.g., a slit pattern or slit structure), the plurality of sub-lines may be arranged in the first direction with a predetermined interval.

FIG. 2A is a view illustrating a first power line and a second-1 power line according to an embodiment of the present invention. FIG. 2B is a view illustrating a second-2 power line and a contact part according to an embodiment of the present invention. FIG. 2C is a cross-sectional view of an area of a display panel in which the first power line and a second power line are formed according to an embodiment of the present invention, and FIG. 2D is a plan view of the area of the display panel in which the first power line and the second power line are formed according to an embodiment of the present invention.

Referring to FIGS. 2A to 2D, the first power line 101 and some parts (hereinafter, referred to as a “second-1 power line 102-1”) of the second power line 102 according to an embodiment of the present invention may be formed in any one layer (e.g., the source-drain layer) of the non-display area NDA having a multilayer structure. According to an embodiment of the present invention, as shown in FIG. 2A, the first power line 101 may be formed in a mesh type (e.g., a mesh structure and/or mesh pattern), and the second-1 power line 102-1 may be formed in a solid type. For example, the second-1 power line 102-1 may be formed as a solid structure. The second-1 power line 102-1 may be formed while being electrically separated (e.g., spaced apart) from the first power line 101. For example, a solid type (e.g., a solid structure) may be a continuous layer that might not have any holes.

In addition, as shown in FIG. 2B, some other parts (hereinafter, a “second-2 power line 102-2”) of the second power line 102 may be formed in another layer (e.g., a layer where the pixels P are formed (hereinafter, the pixel layer)) of the multilayer non-display area NDA. The second-2 power line 102-2 may be formed in a mesh type. In addition, the second-1 power line 102-1, which is formed in one layer, and the second-2 power line 102-2, which is formed in another layer, may be electrically connected with each other by a contact part 102-3, as shown in FIG. 2C. For example, the contact part 102-3 may be a via or an interlayer connection. For example, the contact part 102-3 may be disposed between the second-1 power line 102-1 and the second-2 power line 102-2. As another example, the second-1 power line 102-1 may be disposed below the contact part 102-3, and the second-2 power line 102-2 may be disposed above the contact part 102-3.

The first power line 101 and the second power line 102 (e.g., the second-2 power line 102-2) may be formed so that first intersection points 101a, where sub-lines of the first power line 101 intersect each other, and second intersection points 102a, where sub-lines of the second power line 102 intersect each other, are not overlapped with each other, as shown in FIG. 2D. For example, the first intersection points 101a are not vertically overlapped with the second intersection points 102a. For example, the first intersection points 101a are formed between neighboring sub-lines of the second power line 102, and the second intersection points 102a are formed between neighboring sub-lines of the first power line 101.

FIG. 3A is a view illustrating a first power line and a second-1 power line according to an embodiment of the present invention. FIG. 3B is a view illustrating a second-2 power line and a contact part according to an embodiment of the present invention, and FIG. 3C is a plan view of an area of a display panel in which the first power line and a second power line are formed according to an embodiment of the present invention.

Referring to FIGS. 3A to 3C, a first power line 101 and some parts (hereinafter, referred to as a “second-1 power line”) 102-1 of a second power line 102 according to an embodiment of the present invention may be formed in any one layer (e.g., a source-drain layer) of a non-display area NDA. According to an embodiment of the present invention, as shown in FIG. 3A, the first power line 101 may be formed in a slit type, and the second-1 power line 102-1 may be formed in a solid type.

In addition, as shown in FIG. 3B, some other parts (hereinafter, a second-2 power line) 102-2 of the second power line 102 may be formed in another layer (e.g., a pixel layer where pixels P are formed) of the non-display area NDA. The second-2 power line 102-2 may be formed in a slit type (e.g., having a slit pattern). At this time, the second-1 power line 102-1 and the second-2 power line 102-2 may be electrically connected with each other by a contact part 102-3.

The slit type first power line 101 and the slit type second power line 102 (e.g., the second-2 power line 102-2) may be formed so as not to be overlapped with each other, as shown in FIG. 3C. For example, first sub-lines 101b of the first power line 101 may be alternately arranged with second sub-lines 102b of the second power line 102 on a plane.

The various embodiments of the present invention described above may increase the reliability of the display device 1000. For example, various embodiments of the present invention may minimize an overlapping area, which is formed by the first power line 101 and the second power line 102 overlapping each other. As such, in the various embodiments of the present invention, as the overlapping area, which is formed by the first power line 101 and the second power line 102 overlapping each other, is minimized, it is possible to prevent a short circuit (or minimize the possibility in which a short circuit occurs) between the first power line 101 and the second power line 102. In addition, the various embodiments of the present invention may prevent damage to nearby element and components (e.g., burning or deterioration of the lines) caused by the short circuit between the first power line 101 and the second power line 102 from spreading. Additionally, the configuration of the first and second power lines 101 and 102, such as the use of mesh or slit patterns, may increase heat dissipation and increase electrical performance, further supporting the device's overall durability and efficiency.

FIG. 4 is a view illustrating an electronic device according to an embodiment of the present invention.

Referring to FIG. 4, an electronic device 40 according to an embodiment of the present invention may include various types of electronic devices. For example, the electronic device 40 according to an embodiment of the present invention may include a rigid type, a flexible type, a foldable type, a rollable type or wearable type of portable communication device (e.g., a mobile phone, a smart phone, a smart watch, a tablet, etc.), a computer device (e.g., a laptop, a monitor, etc.), a portable multimedia device (e.g., a portable game console, etc.), a portable medical device, a photographing device (e.g., a digital camera, a camcorder, etc.), a multimedia device installed in, embedded in, or integrally formed with an automobile (e.g., a display for a vehicle, a head-up display, etc.), or a home appliance device (e.g., a television, etc.). In addition, the electronic device 40 according to an embodiment of the present invention is not limited to the above-described devices, and may include various types of products (e.g., an augmented reality or virtual reality display, a billboard, or video wall, etc.).

According to an embodiment of the present invention, the electronic device 40 may include a display device 4000. The display device 4000 may be accommodated in a housing 400 of the electronic device 40. For example, the display device 4000 may be accommodated in the housing 400 such that the display area of the display device 4000 faces a window which may be connected to the housing 400 and may form a front surface of the electronic device 40. The display device 4000 may provide (e.g., display) various images (e.g., still images or moving images).

According to an embodiment of the present invention, the display device 4000 may be the same as or similar to the display device 1000 of FIG. 1. Therefore, the display device 4000 will not be described in detail.

In addition, the display device 4000 may further include a touch panel that may detect a touch input (e.g., finger touch and pen touch). For example, the display device 4000 may include a touch panel separately or integrally formed with the display panel.

Various embodiments of the present invention may form the first power line and the second power line, which are overlapped with each other, in a mesh structure (or e.g., mesh pattern) or a slit structure (or, e.g., slit pattern). In addition, various embodiments of the present invention may arrange the first power line and the second power line in a crossing configuration. Accordingly, various embodiments of the present invention may minimize the overlapping area between the first power line and the second power line.

In addition, in various embodiments of the present invention, as the overlapping area, which is formed by the first power line and the second power line overlapping each other, is minimized, it is possible to reduce the possibility in which a short circuit occurs between the first power line and the second power line. Further, various embodiments of the present invention may prevent damage to the line caused by a short circuit from spreading. This may be achieved by the first power line and second power line having a high resistance due to their structure (e.g., each of the plurality of sub-lines has a narrow width in the mesh structure or the slit structure thus to have a large resistance). Through this, various embodiments of the present invention may increase the reliability of the display device.

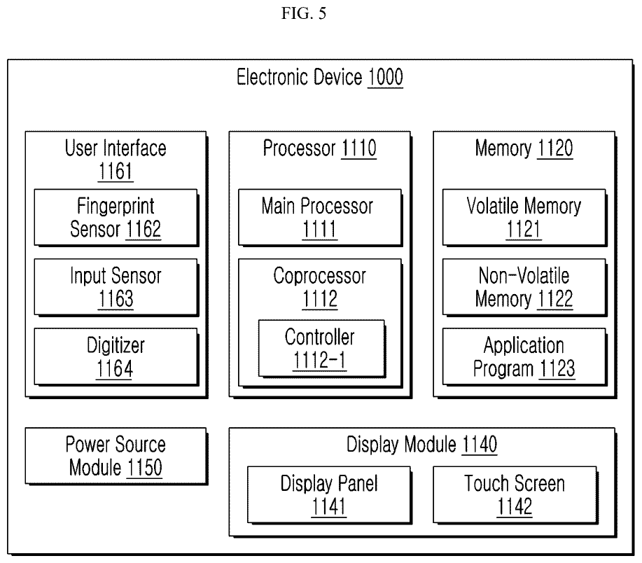

FIG. 5 is a diagram illustrating an electronic device according to an embodiment of the present invention.

Referring to FIG. 5, the electronic device 1000 according to an embodiment of the present invention may output various information (e.g., images, text, music, etc.) through a display module 1140, which, for example, may correspond to the display device 1000 shown in FIG. 1. When a processor 1110 executes an application stored in a memory 1120, the display module 1140 may provide application information to a user through a display panel 1141.

In some embodiments of the present invention, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including the display area DA optimized for compact and high-clarity visuals and the non-display area NDA integrating biometric sensors for health monitoring. In some cases, the electronic device 1000 may be an AR/VR headset.

In some embodiments of the present invention, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

For example, the disclosure about the electronic device 1000 of FIG. 5 may be combinable with the disclosure about the electronic device 40 of FIG. 4.

The term “module” used in various embodiments of the present invention may include a unit implemented in hardware, software or firmware way, and for example, may be used interchangeably with the terms such as logic, a logic block, a part, or a circuit. The module may be a part integrally formed therewith, or a minimum unit of the part or a portion thereof which performs one or more functions. For example, according to an embodiment of the present invention, the module may be implemented in a form of an application-specific integrated circuit (ASIC).

Various embodiments of the present invention may be implemented by software (e.g., a program) including one or more instructions stored in a storage medium (e.g., an internal memory or an external memory) readable by a machine (e.g., an electronic device 40). For example, a processor of the machine (e.g., the electronic device 40) may call, among one or more instructions stored in the storage medium, at least one instruction, and may execute the instruction. This allows at least one function to be performed according to the called at least one instruction. The one or more instructions may include a code that is made by a compiler or a code that may be executed by an interpreter. The storage medium that may be read by a device may be provided in a form of a non-transitory storage medium. Here, the ‘non-transitory storage medium’ means that the storage medium is a tangible device and does not include a signal (e.g., an electromagnetic wave), and with regard to the term, a case, in which data are semi-permanently stored in the storage medium, and a case, in which data are temporarily stored in the storage medium, are not distinguished.

According to an embodiment, the methods according to various embodiments of the present invention may be provided to be included in a computer program product. The computer program product may be traded between a seller and a purchaser. The computer program product may be distributed in a form of a storage medium that may be read by a device (e.g., a compact disk read only memory (CD-ROM)) or may be distributed (e.g., downloaded or uploaded) through an application store or directly or online between two user devices. In the online distribution, at least a portion of the computer program product may be at least temporarily stored in a storage medium, such as a server of a manufacturer, a server of an application store, or a memory of a relay server, which may be read by a device, or temporarily generated.

According to various embodiments, each component or element (e.g., a module or program) of the above-described components or elements may include one or a plurality of entities, and some of the plurality of entities may be disposed to other components with being separated therefrom. According to various embodiments, among the above-described components, one or more components or operations thereof may be omitted or one or more other components or operations thereof may be added to the components. Alternatively or additionally, the plurality of components (e.g., the modules or programs) may be integrated into one component. In this case, the integrated components may perform one or more functions of each component of the plurality of components in a way that they are the same as or similar to the functions performed by the corresponding components among the plurality of components before the integration. According to various embodiments, operations performed by the modules, programs, or other components may be executed sequentially, in parallel, repeatedly, or heuristically, one or more operations may be executed in another sequence or omitted, or one or more other operations may be added thereto.

While the present invention has been described with reference to embodiments thereof, it will be understood by those of ordinary skill in the art that various changes in form and details may be made thereto without departing from the spirit and scope of the present invention.

What is claimed is:

1. A display device comprising:
a display panel including a display area and a non-display area, wherein the display area includes a plurality of pixels, and the non-display area is disposed adjacent to the display area;
a first power line formed in a first layer of the non-display area, and configured to supply driving power to each pixel of the plurality of pixels; and
a second power line including a first part that is formed in the first layer and a second part that is formed in a second layer of the non-display area so as to be overlapped with the first power line, and configured to supply common power to each pixel of the plurality of pixels,
wherein the first power line includes a plurality of first sub-lines that are arranged to form a mesh structure, and the second power line includes a plurality of second sub-lines that are arranged to form the mesh structure, and
wherein a plurality of first intersection points, which are formed by intersections between the plurality of first sub-lines of the first power line, and a plurality of second intersection points, which are formed by intersections between the plurality of second sub-lines of the second power line, do not overlap each other.

2. The display device according to claim 1, wherein the first power line is formed in a source-drain layer of the non-display area.

3. The display device according to claim 2, wherein the second power line comprises:
a second-1 power line formed in a same layer as the first power line while being spaced apart from the first power line;
a second-2 power line formed in a different layer from the second-1 power line; and
a contact part which electrically connects the second-1 power line and the second-2 power line to each other.

4. The display device according to claim 3, wherein the second-2 power line is formed in a pixel layer where the plurality of pixels are formed.

5. The display device according to claim 3, wherein the second-1 power line has a solid structure, and
the second-2 power line has the mesh structure.

6. The display device according to claim 1, further comprising a substrate which has one end connected to the display panel, and which comprises a driving element configured to control driving of the display panel.

7. A display device comprising:
a display panel including a display area and a non-display area, wherein the display area includes a plurality of pixels, and the non-display area is disposed adjacent to the display area;
a first power line formed in a first layer of the non-display area, and configured to supply driving power to each pixel of the plurality of pixels; and
a second power line including a first part that is formed in the first layer and a second part that is formed in a second layer of the non-display area so as to be overlapped with the first power line, and configured to supply common power to each pixel of the plurality of pixels,
wherein the first power line includes a plurality of first sub-lines that are arranged in a first direction to form a slit structure, and the second power line includes a plurality of second sub-lines that are arranged in the first direction to form the slit structure, and
the plurality of first sub-lines of the first power line do not overlap the plurality of second sub-lines of the second power line.

8. The display device according to claim 7, wherein the first power line is formed in a source-drain layer of the non-display area.

9. The display device according to claim 8, wherein the second power line comprises:
a second-1 power line formed in a same layer as the first power line while being spaced apart from the first power line;
a second-2 power line formed in a different layer from the second-1 power line; and
a contact part which electrically connects the second-1 power line and the second-2 power line to each other.

10. The display device according to claim 9, wherein the second-2 power line is formed in a pixel layer where the plurality of pixels are formed.

11. The display device according to claim 9, wherein the second-1 power line has a solid structure, and
the second-2 power line has the slit structure.

12. The display device according to claim 7, further comprising a substrate which has one end connected to the display panel, and which comprises a driving element configured to control driving of the display panel.

13. An electronic device, comprising:
a housing; and
a display device mounted in the housing,
wherein the display device comprises:
a display panel which comprises a display area and a non-display area, wherein the display area includes a plurality of pixels, and the non-display area is disposed adjacent to the display area;
a first power line formed in a first layer of the non-display area, and configured to supply driving power to each pixel of the plurality of pixels; and
a second power line including a first part that is formed in the first layer and a second part that is formed in a second layer of the non-display area so as to be overlapped with the first power line, and configured to supply common power to each pixel of the plurality of pixels,
wherein each of the first power line and the second power line includes a slit structure or a mesh structure.

14. The electronic device according to claim 13, wherein the first power line includes a plurality of first sub-lines, and when the first power line has the mesh structure, the plurality of first sub-lines are arranged to form the mesh structure, and the second power line includes a plurality of second sub-lines that are arranged to form the mesh structure, and a plurality of first intersection points of the first power line do not overlap a plurality of second intersection points of the second power line.

15. The electronic device according to claim 13, wherein the first power line includes a plurality of first sub-lines, and when the first power line has the slit structure, the plurality of first sub-lines are arranged in a first direction to form the slit structure, and the second power line includes a plurality of second sub-lines that are arranged in the first direction to form the slit structure, and the plurality of first sub-lines of the first power line do not overlap the plurality of second sub-lines of the second power line.

16. The electronic device according to claim 13, wherein the second power line comprises:
a second-1 power line formed in a same layer as the first power line while being spaced apart from the first power line;
a second-2 power line formed in a different layer from the second-1 power line; and
a contact part which electrically connects the second-1 power line and the second-2 power line to each other.

17. The electronic device according to claim 16, wherein the first power line and the second-1 power line are formed in a source-drain layer of the non-display area.

18. The electronic device according to claim 16, wherein the second-2 power line is formed in a pixel layer where the plurality of pixels are formed.

19. The electronic device according to claim 16, wherein the second-1 power line has a solid structure, and
the second-2 power line has the mesh structure or the slit structure.

20. The electronic device according to claim 13, further comprising a substrate which has one end connected to the display panel, and which comprises a driving element configured to control driving of the display panel.
